(19) United States
(12) Patent Application Publication
(10) Pub. No.: US 2008/0185687 A1
(43) Pub. Date: Aug. 7, 2008

(54) MEMORY DEVICE AND METHOD FOR FABRICATING THE SAME

(75) Inventors: Jin-Pyo Hong, Seoul (KR); Young-Ho Do, Seoul (KR); June-Sik Kwak, Seoul (KR); Koo-Woong Jeong, Seoul (KR); Min-Su Park, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Industry-University Cooperation Foundation Hanyang University, Seoul (KR)

(21) Appl. No.: 12/026,322

(22) Filed: Feb. 5, 2008

(30) Foreign Application Priority Data
Feb. 7, 2007 (KR) 10-2007-0012751
Feb. 4, 2008 (KR) 10-2008-0011204

(51) Int. Cl. H01L 29/86; H01L 21/02

(52) U.S. Cl. 257/536; 438/385; 257/E29.325; 257/E21.006

(57) ABSTRACT

A memory device includes a lower electrode layer formed over a substrate, a resistance layer including a metal nitride layer formed over the lower electrode layer, and an upper electrode layer formed over the resistance layer.

### CROSS-REFERENCE TO RELATED APPLICATIONS

The present invention claims priority of Korean patent application numbers 10-2007-0012751 and 10-2008-0011204, filed on Feb. 7, 2007 and Feb. 4, 2008, respectively, which are incorporated by reference in their entirety.

### BACKGROUND OF THE INVENTION

The present invention relates to a non-volatile or volatile memory device and a method for fabricating the same and more particularly, to a memory device which stores bit data ‘0’ or ‘1’ determined based on resistance variation. In detail, the present invention relates to a resistive random access memory (ReRAM) device with high efficiency and good reproducibility and a method for fabricating the same.

Studies on devices based on a charge control of electrons will reach the limit in several years as mobile and digital telecommunication industries and appliances' industries have been rapidly developed. Thus, it is required to develop memory devices which employ a new concept not the typical charge control.

A current personal computer (PC)-centered market structure may be changed into a non-PC-centered market structure. This indicates a memory having large capacity will be used in information devices. Therefore, it is required to develop a new technology for fabricating next generation, high capacity, very high speed, very low power memory devices.

A flash memory device which represents the non volatile memory devices needs a high operating voltage when writing or erasing data. When scaling down the device to 65 nm or less, it reaches the limit due to a noise between neighboring cells. Furthermore, high power consumption is required as well as low speed.

In case of a ferro-electric RAM (FeRAM), it has a problem on a material stability. A magnetic RAM (MRAM) is formed by a complicate process, and has a multi-layered structure and a small read/write margin.

Thus, the development of a technology for fabricating next generation memory devices such as a non volatile memory device is essential to enhance national competitiveness.

The ReRAM device represents a non volatile memory device using a rapid resistance variation of a thin film according to a certain voltage applied to the thin film.

The ReRAM device is not deteriorated when unlimitedly writing or restoring data and can operate at a high temperature. Furthermore, since the ReRAM device is a non volatile memory, data stability is secured. When an input pulse is coupled thereto, the ReRAM device can operate at a speed of 10 ns to 20 ns in the resistance variation of more than 1,000 times. Since a resistance layer of the ReRAM device has a single layer, the device can be highly integrated and operate with a high speed. Furthermore, since typical complementary metal oxide semiconductor (CMOS) and integration processes can be applied to the fabrication of the ReRAM, it is possible to minimize energy consumption.

The resistance layer of the ReRAM device has been usually formed with an oxide. In detail, the oxide includes a binary oxide and a perovskite oxide. Recently, the resistance layer is made of the perovskite oxide doped with metal or containing metal.

Korean Patent Publication No. 2006-83368 discloses a ReRAM device that includes a resistance layer formed with multi layers containing metal oxides, each metal oxides having different composition ratios. The metal oxide includes one of zirconium oxide (ZrO_{X}), nickel oxide (NiO_{X}), hafnium oxide (HfO_{X}), titanium oxide (TiO_{X}), tantalum oxide (Ta₂O_{X}), aluminum oxide (Al₂O_{X}), lanthanum oxide (La₂O_{X}), niobium oxide (Nb₂O_{X}), strontium titanium oxide (SrTiO_{X}), SrTiO_{X} doped with chromium (Cr), and SrZrO_{X} doped with Cr. In this case, the x ranges from 1.5 to 1.9.

Korean Patent Publication No. 2006-106035 discloses a ReRAM device including a resistance layer formed with perovskite oxide of SrZrO₃ doped with Cr.

Korean Patent Publication No. 2005-17394 discloses a ReRAM device including a barrier layer formed over an iridium (Ir) substrate and a Pr_{0.7}Ca_{0.3}MnO₃ (PCMO) thin film formed over the barrier layer as a resistance layer. The barrier layer includes one of tantalum (Ta), tantalum nitride (TaN), titanium (Ti), titanium nitride (TiN), tantalum aluminum nitride (TaAlN), titanium silicon nitride (TiSiN), tantalum silicon nitride (TaSiN), titanium aluminum (TiAl), and titanium aluminum nitride (TiAlN). Since coating, baking, and annealing processes are repeatedly performed until obtaining a desired thickness of the resistance layer, a whole fabrication process of this ReRAM device is very complicated. Since major processes are complicatedly performed, a characteristic of the ReRAM device can be influenced by oxidation and surface pollution.

Furthermore, as shown in the above publications, when the oxide-based materials are used as the resistance layer, interface treatment and oxide may cause pollution during the fabrication process. Thus, it is difficult to secure good reproducibility and operational stability of the device due to limitations of the fabrication process.

Therefore, there are required methods for fabricating memory devices through a simple process without the surface pollution, which are applicable to various memory devices including non volatile memory devices. In addition, studies of using other materials instead of the oxide to fabricate the memory devices are in progress.

### SUMMARY OF THE INVENTION

Embodiments of the present invention are directed to provide a memory device and a method for fabricating the same, and a non-volatile resistive random access memory (ReRAM) device and a method for fabricating the same.

This invention provides a memory device and a non-volatile ReRAM device with high efficiency and good reproducibility by employing a resistance layer containing metal nitride instead of a perovskite-based oxide or a binary oxide.

This invention also provides a method for fabricating a memory device and a non-volatile ReRAM device, which can prevent the generation of a surface pollution and oxygen defects with a simple process.

In accordance with an aspect of the present invention, there is provided a memory device including a lower electrode layer formed over a substrate, a resistance layer including a metal nitride layer formed over the lower electrode layer, and an upper electrode layer formed over the resistance layer.

In accordance with another aspect of the present invention, there is provided a non-volatile resistive random access memory (ReRAM) device including a lower electrode layer formed over a substrate, a resistance layer including a metal nitride layer formed over the lower electrode layer, and an upper electrode layer formed over the resistance layer.

In accordance with still another aspect of the present invention, there is provided a method for fabricating a memory device, the method including providing a substrate, forming a lower electrode layer over the substrate, forming a resistance layer including a metal nitride layer over the lower electrode layer, and forming an upper electrode layer over the resistance layer.

In accordance with further still another aspect of the present invention, there is provided a method for fabricating a non-volatile ReRAM device, the method comprising providing a substrate, forming a lower electrode layer over the substrate, forming a resistance layer including a metal nitride layer over the lower electrode layer, and forming an upper electrode layer over the resistance layer.

### BRIEF DESCRIPTION OF THE DRAWINGS

FIG. 1 illustrates a cross-sectional view of a non-volatile ReRAM device in accordance with an embodiment of the present invention.

FIGS. 2A to 2D are cross-sectional views of a method for fabricating a non-volatile ReRAM device in accordance with an embodiment of the present invention.

FIG. 3 is a graph showing a voltage-current characteristic of a non-volatile ReRAM in accordance with a first embodiment of the present invention.

FIG. 4 is a graph showing a voltage-current characteristic of a non-volatile ReRAM in accordance with a comparative example.

FIG. 5 is a graph showing a set/reset characteristic of the non-volatile ReRAM in accordance with the first embodiment of the present invention.

FIG. 6 is a graph showing resistance variation when the non-volatile ReRAM in accordance with the first embodiment of the present invention is in a low resistance state (IRS) and a high resistance state (HRS).

### DESCRIPTION OF SPECIFIC EMBODIMENTS

Embodiments of the present invention relate to a memory device and a method for fabricating the same.

To describe this invention, a non-volatile ReRAM memory device is used as an example.

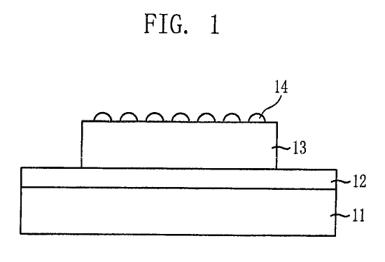

FIG. 1 illustrates a cross-sectional view of a ReRAM device in accordance with an embodiment of the present invention.

Referring to FIG. 1, the ReRAM device includes a substrate 11, a lower electrode layer 12 formed over a substrate 11, a resistance layer 13 formed over the lower electrode layer 12, and an upper electrode layer 14 formed over the metal nitride layer 13.

The substrate 11 may include any materials which can be applied to general semiconductor memory devices. For instance, the substrate 11 may be one of a silicon (Si) substrate, a silicon oxide (SiO₂) substrate, a multi-layered substrate of Si and SiO₂, and a polysilicon substrate.

The lower electrode layer 12 may include one of platinum (Pt), gold (Au), aluminum (Al), copper (Cu), titanium (Ti) and a combination thereof. A thickness of the lower electrode layer 12 ranges from approximately 5 nm to approximately 500 nm. The thickness of the lower electrode layer 12 changes in the above range according to a kind of electrode materials.

In accordance with the present invention, a metal nitride layer 13 is used to form the resistance layer of the ReRAM device. The metal nitride layer 13 is made of a metal nitrogen (MN)-based compound. The metal (M) includes one of aluminum (Al), iron (Fe), cobalt (Co), chromium (Cr) and a combination thereof. Desirably, the metal nitride layer 13 is made of Al. The metal nitride layer 13 includes a material other than the perovskite-based oxide and the binary oxide used as a resistance layer in the typical non-volatile ReRAM device. Furthermore the metal nitride layer 13 is different from a TiN layer used as a barrier layer not a resistance layer when using the oxide.

The present invention uses the metal nitride layer 13 as the resistance layer. Thus, when a certain voltage is applied to the metal nitride layer 13, a resistance state of the metal nitride layer 13 changes to operate the RERAM device, like the typical resistance layer made of the typical perovskite-based oxide or the binary oxide. That is, the resistance layer, i.e., the metal nitride layer 13, is in a high resistance state (HRS) or a low resistance state (LRS), each corresponding to bit data ‘0’ or ‘1’, according to a bias applied to the lower and the upper electrode layers 12 and 14. In detail, when the HRS corresponds to the bit data ‘0’, the LRS corresponds to the bit data ‘0’. When the HRS corresponds to the bit data ‘1’, the LRS corresponds to the bit data ‘0’.

In accordance with an embodiment of the present invention, a thickness of the metal nitride layer 13 ranges from approximately 10 nm to approximately 500 nm, desirably, from approximately 50 nm to approximately 200 nm. If the thickness of the metal nitride layer 13 is less than 10 nm, a set/reset voltage, i.e., an operation voltage, becomes unstable. Thus, it is difficult to operate the ReRAM device. On the other hand, if the thickness of the metal nitride layer 13 is greater than 500 nm, the operation voltage of the ReRAM increases, thereby causing high power consumption to drive the ReRAM device.

The upper electrode layer 14 may include the same material as the lower electrode layer 12 includes or not. Desirably, the upper electrode layer 14 includes one of Pt, Au, Al, Cu, Ti and a combination thereof. A thickness of the upper electrode layer 14 ranges from approximately 5 nm to 500 nm. The thickness of the upper electrode layer 14 is changed according to a kind of electrode materials. The upper electrode layer 14 has a patterned structure obtained by performing a shadow masking process or a dry etching process.

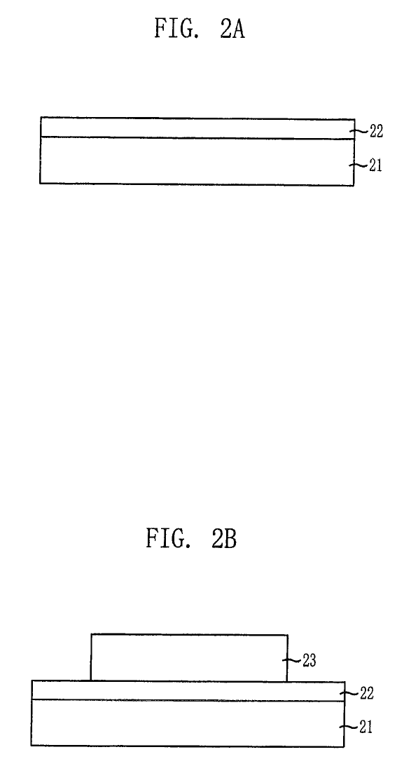

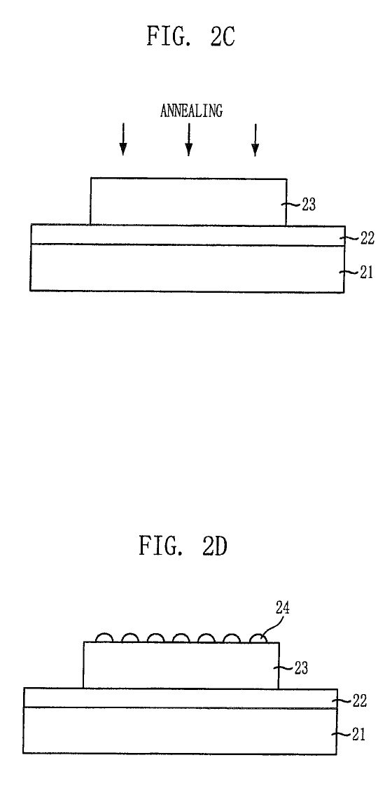

FIGS. 2A to 2D describe cross-sectional views of a method for fabricating a non-volatile ReRAM device in accordance with an embodiment of the present invention.

Referring to 2A, a lower electrode layer 22 is formed over a substrate 21 by a deposition process. The lower electrode layer 22 includes one of Pt, Au, Al, Cu, Ti and a combination thereof. The deposition process may be one of physical vapor deposition (PVD), chemical vapor deposition (CVD), sputtering, pulsed laser deposition (PLD), thermal evaporation, electron beam evaporation, atomic layer deposition (ALD), and molecular beam epitaxy (MBE) processes.

Referring to FIG. 2B, a metal nitride layer 23 is formed over the lower electrode layer 22. The metal nitride layer 23 is formed by one of the above described deposition processes. Particularly, the metal nitride layer 23 is formed through the sputtering process.

The sputtering process is performed using a gas mixture of argon (Ar) and nitrogen (N₂) at a pressure in the range of approximately 3 mTorr to approximately 10 mTorr. The N₂ occupies approximately 10% to approximately 50% of the gas mixture.

Referring to FIG. 2C, the substrate 21 where the lower electrode layer 22 and the metal nitride layer 23 are formed is thermal-treated, i.e., annealed.

The thermal treatment is performed for approximately 1 minute to approximately 24 hours, desirably approximately 30 minutes to approximately 3 hours, at a temperature in the range of approximately 100° C. to approximately 1,000° C., desirably approximately 600° C. to approximately 900° C. The thermal treatment is performed under a nitrogen (N₂) atmosphere where N₂ gas is applied at a partial pressure of approximately 100 Torr to approximately 500 Torr, or a vacuum condition.

Through the thermal treatment, lattices in the metal nitride layer 23 are rearranged to remove unstableness of an operation voltage or current caused by defects or vacancies of lattices.

Conditions for the thermal treatment can be changed according to characteristics of materials to be thermal-treated. However, it is desirable to perform the thermal treatment under the above-mentioned conditions. If the conditions for the thermal treatment do not reach the above range, an insufficient thermal energy is provided, so that the rearrangement of the lattices is insufficiently executed. Thus, the stability of the operation voltage or current may be deteriorated. On the other hand, if the conditions for the thermal treatment process exceed the above-mentioned range, composition or crystalline state of the metal nitride layer 23 may be changed or a portion of the composition in the metal nitride layer 23 may be diffused to other layers.

Referring to FIG. 2D, an upper electrode material is deposited over the metal nitride layer 23. The upper electrode material includes one of Pt, Au, Al, Cu, Ti and a combination thereof. A shadow masking or dry etching process is performed to form an upper electrode layer 24 by patterning the upper electrode material film formed over the metal nitride layer 23.

The upper electrode layer 24 is formed by the deposition process described referring to FIG. 2A.

Baking and post-annealing processes can be additionally performed on a resultant structure including the upper electrode layer 24.

In accordance with the present invention, the lower electrode layer, the upper electrode layer, and the metal nitride layer can be formed by the identical deposition method so as to simplify the process. Furthermore, since the metal nitride layer is formed under the vacuum condition, oxygen (O₂) defect formation and surface pollution of the metal nitride layer are minimized compared to the typical process which uses the perovskite oxide or the binary oxide as the resistance layer.

Although an operation mechanism of the non-volatile ReRAM device is not clearly stipulated, it is known that the ReRAM device is operated by a resistance switching mechanism of the resistance layer. In detail, when a voltage is applied thereto, the non-volatile ReRAM device has resistance variation of more than 100 times between a low resistance and a high resistance thereof. Thus, it is possible to write/erase data with high speed, having good thermal stability.

In particular, the ReRAM device in accordance with an embodiment of the present invention has the resistance variation, i.e., resistance ratio or on/off ratio between a low resistance and a high resistance, in the range of about 100 to about 8,000. That is, the high resistance is about 100 to about 8,000 times greater than the low resistance. It is preferable that the resistance ratio is about 250 to about 5,000.

As the ReRAM device in accordance with an embodiment of the present invention has the AlN layer as the resistance layer, its set/reset voltage characteristic is improved compared to the typical oxide, e.g., magnesium oxide (MgO). In addition, the resistance ratio of a low resistance state (LRS) to a high resistance state (HRS) is approximately 300. This result indicates the resistance ratio of this invention is substantially higher than that of the typical device which uses the oxide as the resistance layer. For example, when using the perovskite oxide as the resistance layer, the resistance ratio between low resistance and the high resistance becomes about 10 to about 50.

The ReRAM device in accordance with the embodiments of the present invention can consume a low power, performs an almost infinite write/read operation, speedily reboots the PC, and safely stores large amount of data.

Hereinafter, the present invention will be described in detail with reference to the specified embodiments. The embodiments of the present invention are illustrative and not limitative.

In accordance with a first embodiment of the present invention, Pt is sputtered over a Si substrate to form a lower electrode layer to have a thickness of approximately 5 nm. Then, AlN is sputtered on the lower electrode layer to form an AlN layer having a thickness of approximately 50 nm. At this time, the sputtering process is performed using a gas mixture of Ar and N₂ at a pressure of approximately 10 mTorr, wherein the N₂ gas occupies 20% of the gas mixture. A thermal treatment is performed on the resultant structure including the AlN layer for approximately 30 minutes at a temperature of approximately 700° C. and at a nitride partial pressure of approximately 500 Torr. Then, Pt is sputtered on the AlN layer to form an upper electrode layer having a thickness of 5 nm, thereby forming a resultant structure.

Processes performed in a second embodiment of the present invention are substantially the same as those performed in the first embodiment, except forming an iron nitride (FeN) layer as the resistance layer to have a thickness of approximately 100 nm, instead of the AlN layer.

Processes performed in a third embodiment of the present invention are substantially the same as those performed in the first embodiment, except forming a CoN layer to have a thickness of 100 nm, instead of the AlN layer.

Processes performed in a fourth embodiment of the present invention are substantially the same as those performed in the first embodiment, except forming a CrN layer to have a thickness of 100 nm, instead of the AlN layer.

Referring to a comparative example, the processes are substantially the same as those performed in the first embodiment except forming an MgO layer as the resistance layer instead of the AlN layer.

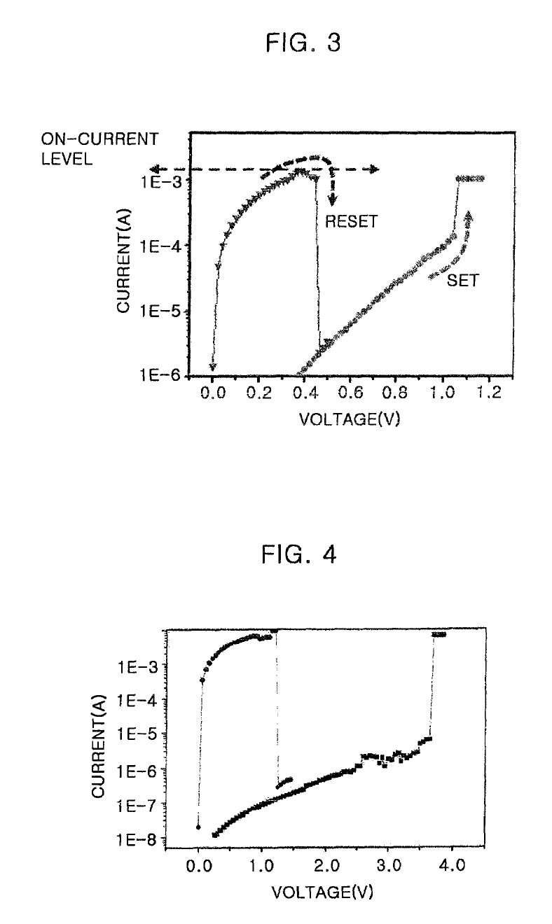

FIG. 3 is a graph showing a voltage-current characteristic of a resultant structure formed in accordance with the first embodiment.

FIG. 4 is a graph showing a voltage-current characteristic of a resultant resistive structure formed in accordance with the comparative example.

Referring to FIGS. 3 and 4, the first embodiment employing the metal nitride layer as the resistance layer shows an improved set voltage of 1.2 V compared to 4 V of the comparative example employing the metal oxide layer as the resistance layer and an improved reset voltage of 0.5 V compared to 1.2 V of the comparative example.

That, in the first embodiment, the set voltage of 4 V is decreased to 1.2 V and the reset voltage of 1.2 V decreases to 0.5 V compared to the comparative example which uses the metal oxide layer as the resistance layer. That is, the metal nitride layer is formed by applying a low bias and the small set and reset voltages.

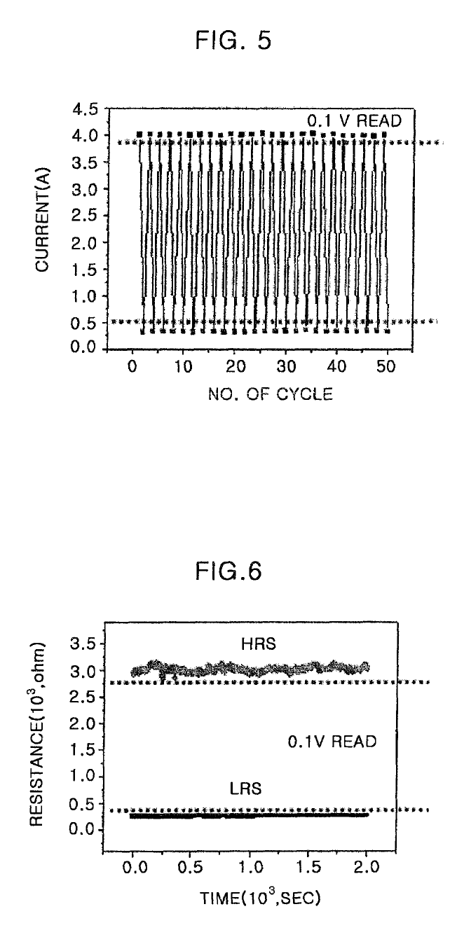

FIG. 5 is a graph showing a set/reset characteristic of the resultant structure in accordance with the first embodiment of the present invention. Referring to FIG. 5, the resultant structure in the first embodiment has a set or a reset state according to a voltage inputted thereto.

FIG. 6 is a graph showing resistance variation when the resultant structure in accordance with the first embodiment of the present invention is in a low resistance state (IRS) and a high resistance state (HRS).

Referring to FIG. 6, resistivity in the LRS is about 0.1×10³Ω and that in the HRS is about 3.0×10³Ω. Therefore, a resistance ratio, i.e., on/off ratio, of the two resistance states is approximately 300. Compared to the typical method, the present invention has a substantially improved resistance ratio.

In accordance with the embodiments of the present invention, there are provided non-volatile ReRAM devices using the metal nitride layer as the resistance layer so as to embody non-volatile memory devices with high efficiency. Furthermore, the non-volatile ReRAM device has an increased resistance ratio, i.e., on/off ratio, thereby improving device applicability.

In accordance with the present invention, the method for fabricating the ReRAM device is simplified and thus it is possible to significantly reduce the generation of defects and prevent surface pollution of the metal nitride layer unlike the typical method using the oxide as the resistance layer.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A memory device, comprising:
a lower electrode layer formed over a substrate;
a resistance layer including a metal nitride layer formed over the lower electrode layer; and
an upper electrode layer formed over the resistance layer.

2. The device of claim 1, wherein the resistance layer has a high resistance state (HRS) or a low resistance state (LRS) corresponding to bit data ‘0’ or ‘1’ according to a bias applied to the lower and upper electrode layers.

3. The device of claim 1, wherein the metal nitride layer includes an MN-based compound, M and N being metal and nitrogen, respectively.

4. The device of claim 3, wherein the M includes one selected from a group consisting of aluminum (Al), iron (Fe), cobalt (Co), chromium (Cr) and a combination thereof.

5. The device of claim 1, wherein the metal nitride layer is made of aluminum nitride (AlN).

6. The device of claim 2, wherein the HRS has resistivity approximately 100 to approximately 8,000 times greater than the LRS.

7. The device of claim 2, wherein the HRS has resistivity approximately 250 to approximately 5,000 times greater than the LRS.

8. The device of claim 5, wherein the HRS has resistivity approximately 300 times greater than the LRS.

9. The device of claim 1, wherein the metal nitride layer has a thickness of approximately 10 nm to approximately 500 nm.

10. The device of claim 1, wherein the metal nitride layer has a thickness of approximately 50 nm to approximately 200 nm.

11. The device of claim 1, wherein the substrate is one of a silicon (Si) substrate, a silicon oxide (SiO₂) substrate, a multi-layered substrate of Si and SiO₂, and a polysilicon substrate.

12. The device of claim 1, wherein each of the lower and the upper electrode layers includes one selected from a group consisting of platinum (Pt), gold (Au), aluminum (Al), copper (Cu), titanium (Ti), and a combination thereof, the lower and the upper electrode layer being made of the same or different materials.

13. A non-volatile resistive random access memory (ReRAM) device, comprising:
a lower electrode layer formed over a substrate;
a resistance layer including a metal nitride layer formed over the lower electrode layer; and
an upper electrode layer formed over the resistance layer.

14. The device of claim 13, wherein the resistance layer has in a HRS or a LRS corresponding to bit data ‘0’ or ‘1’ according to a bias applied to the lower and the upper electrode layers.

15. The device of claim 13, wherein the metal nitride layer includes an MN-based compound, M and N being metal and nitrogen, respectively.

16. The device of claim 15, wherein the M includes one selected from a group consisting of Al, Fe, Co, Cr, and a combination thereof.

17. The device of claim 13, wherein the metal nitride layer is made of AlN.

18. The device of claim 14, wherein the HRS has resistivity approximately 100 to approximately 8,000 times greater than the LRS.

19. The device of claim 14, wherein the HRS has resistivity approximately 250 to approximately 5,000 times greater than the LRS.

20. The device of claim 17, wherein the HRS has resistivity approximately 300 times greater than the LRS.

21. The device of claim 13, wherein the metal nitride layer has a thickness of approximately 10 nm to approximately 500 nm.

22. The device of claim 13, wherein the metal nitride layer has a thickness of approximately 50 nm to approximately 200 nm.

23. The device of claim 13, wherein the substrate is one of a Si substrate, a SiO₂ substrate, a multi-layered substrate of Si and SiO₂, and a polysilicon substrate.

24. The device of claim 13, wherein each of the lower and the upper electrode layers includes one selected from a group consisting of Pt, Au, Al, Cu, Ti, and a combination thereof, the lower and the upper electrode layer being made of the same or different materials.

25. A method for fabricating a memory device, the method comprising:
providing a substrate;
forming a lower electrode layer over the substrate;
forming a resistance layer including a metal nitride layer over the lower electrode layer; and
forming an upper electrode layer over the resistance layer.

26. The method of claim 25, after forming the resistance layer, further comprising performing a thermal treatment on the substrate where the lower electrode layer and the resistance layer are formed.

27. The method of claim 25, wherein the metal nitride layer includes an MN-based compound, M and N being metal and nitrogen, respectively.

28. The method of claim 27, wherein the M includes one selected from a group consisting of Al, Fe, Co, Cr and a combination thereof.

29. The method of claim 25, wherein the metal nitride layer is made of AlN.

30. The method of claim 25, wherein each of the lower electrode layer, the metal nitride layer, and the upper electrode layer is formed by performing one of physical vapor deposition (PVD), chemical vapor deposition (CVD), sputtering, pulsed laser deposition (PLD), thermal evaporation, electron beam evaporation, atomic layer deposition (ALD), and molecular beam epitaxy (MBE) processes.

31. The method of claim 25, wherein the metal nitride layer is formed by performing a sputtering process.

32. The method of claim 31, wherein the metal nitride layer is formed using a gas mixture of argon (Ar) and nitrogen (N₂) at a pressure in the range of approximately 3 mTorr to approximately 10 mTorr, the nitrogen gas occupying approximately 10% to approximately 50% of the gas mixture.

33. The method of claim 26, wherein the thermal treatment is performed at a temperature in the range of approximately 600° C. to approximately 900° C.

34. The method of claim 26, wherein the thermal treatment is performed at a temperature in the range of approximately 100° C. to approximately 1,000° C.

35. The method of claim 26, wherein the thermal treatment is performed under a N₂ atmosphere where a N₂ gas is applied at a partial pressure of approximately 100 Torr to approximately 500 Torr, or a vacuum condition.

36. A method for fabricating a non-volatile ReRAM device, the method comprising:
providing a substrate;
forming a lower electrode layer over the substrate;
forming a resistance layer including a metal nitride layer over the lower electrode layer; and
forming an upper electrode layer over the resistance layer.

37. The method of claim 36, after forming the resistance layer, further comprising performing a thermal treatment on the substrate where the lower electrode layer and the resistance layer are formed.

38. The method of claim 36, wherein the metal nitride layer includes an MN-based compound, M and N being metal and nitrogen, respectively.

39. The method of claim 38, wherein the M includes one selected from a group consisting of Al, Fe, Co, Cr and a combination thereof.

40. The method of claim 36, wherein the metal nitride layer is made of AlN.

41. The method of claim 36, wherein each of the lower electrode layer, the metal nitride layer, and the upper electrode layer is formed by performing one of PVD, CVD, PLD, thermal evaporation, electron beam evaporation, ALD, and MBE processes.

42. The method of claim 36, wherein the metal nitride layer is formed by performing a sputtering process.

43. The method of claim 36, wherein the metal nitride layer is formed using a gas mixture of argon (Ar) and nitrogen (N₂) at a pressure in the range of approximately 3 mTorr to approximately 10 mTorr, the nitrogen gas occupying approximately 10% to approximately 50% of the gas mixture.

44. The method of claim 37, wherein the thermal treatment is performed at a temperature in the range of approximately 600° C. to approximately 900° C.

45. The method of claim 37, wherein the thermal treatment is performed at a temperature in the range of approximately 100° C. to approximately 1,000° C.

46. The method of claim 37, wherein the thermal treatment is performed under a N₂ atmosphere where a N₂ gas is applied at a partial pressure of approximately 100 Torr to approximately 500 Torr, or a vacuum condition.
